(19) United States
(12) Patent Application Publication
(10) Pub. No.: US 2026/0349031 A1
(43) Pub. Date: Nov. 5, 2026

(54) CIRCUIT FOR BUILT-IN SELF-REPAIR OF DEFECTIVE THROUGH-SILICON VIAS (TSVS) IN 3D INTEGRATED CIRCUITS (ICS)

(71) Applicant: NATIONAL TSING HUA UNIVERSITY, Hsinchu (TW)

(72) Inventors: Shi-Yu HUANG, Hsinchu (TW); Chen-Yu HUANG, Hsinchu (TW)

(73) Assignee: NATIONAL TSING HUA UNIVERSITY, Hsinchu (TW)

(21) Appl. No.: 19/271,468

(22) Filed: Jul. 16, 2025

(30) Foreign Application Priority Data
May 2, 2025 (TW) 114116597

(51) Int. Cl. G01R 31/3185; H10B 12/00; H10W 20/20; H10W 90/00; H10W 90/20

(52) U.S. Cl. CPC G01R 31/318513; G01R 31/318541; G01R 31/31855; H10B 12/50; H10W 20/20; H10W 90/00; H10W 90/284; H10W 90/297

(57) ABSTRACT

An electronic device includes TSVs including a plurality of redundant TSVs; and dies electronically cascaded to each other through the TSVs and including a base layer and a plurality of memory layers. The base layer includes a driving wrapper circuit transmitting a pulse signal to the TSVs, selecting one of the redundant TSVs based on a test result of the pulse signal to transmit the pulse signal in the next test; and a main controller outputting a double pulse signal, determining the test result, and broadcasting the test result. Each memory layer includes a receiving wrapper circuit receiving the pulse signal, selecting the one of the redundant TSVs based on the test result; and a sub-controller receiving the test result, and sending the test result to the receiving wrapper circuit. In the next test, the pulse width of the pulse signal is shortened.

### CROSS REFERENCE TO RELATED APPLICATIONS

This Application claims priority of Taiwan Application No. 114116597, filed on, May 2, 2025, the entirety of which is incorporated by reference herein.

### BACKGROUND OF THE INVENTION

### Field of the Invention

The present invention relates to an electronic device, and, in particular, it relates to an electronic device and a method with built-in self-repair through-silicon vias.

### Description of the Related Art

In recent years, three-dimensional dynamic random-access memory (3D-DRAM) using through-silicon vias (TSVs) has demonstrated that it has many advantages, such as reducing the interconnect length, increasing the bandwidth, and lowering power consumption. The use of this type of memory has become increasingly widespread. However, manufacturing defects may occur in TSVs and their micro-bumps, causing significant yield loss, especially in the final stages of 3D-DRAM manufacture.

The faults that routinely occur in TSVs can be approximately categorized as “hard open/short faults” or “resistive open/short faults”. Resistive open/short faults can cause “delay fault”, since these malfunctions increase the propagation delay of the affected TSV. Although a 100 picosecond (ps) delay may seem harmless in some logic circuits, this can adversely impact the performance of high-speed GHz range 3D-DRAM, and even cause functional failures. Therefore, addressing these issues is critical.

With improvements of the semiconductor technology, the pitch size of micro-bumps continues to be scaled down. This scaling down increases the possibility of short faults, further challenging the reliability of TSVs in 3D-DRAM.

### BRIEF SUMMARY OF THE INVENTION

An electronic device, in accordance with the embodiments of the present invention, includes a plurality of through-silicon vias (TSVs), including a plurality of redundant TSVs; and a plurality of dies, electronically cascaded to each other through the TSVs. The dies include a base layer and a plurality of memory layers. The base layer comprises a driving wrapper circuit and a main controller. The driving wrapper circuit transmits a pulse signal to the TSVs. Based on the test result of the pulse signal, the driving wrapper circuit selects one of the redundant TSVs for transmitting the pulse signal in the next test. The main controller outputs a double pulse signal, and broadcasts the test result. Each of the memory layers comprises a receiving wrapper circuit and a sub-controller. The receiving wrapper circuit selects a redundant TSV to receive the pulse signal based on the test result. The sub-controller receives the test result and sends the test result to the receiving wrapper circuit. In the next test, the pulse width of the pulse signal is shortened.

According to the electronic device described above, based on the double pulse signal, the driving wrapper circuit generates the pulse signal. The main controller shortens the time interval between two rising edges of the double pulse signal such that the driving wrapper circuit shortens the pulse width of the pulse signal.

According to the electronic device described above, the driving wrapper circuit comprises a plurality of driving units. Each of the driving units is electronically coupled to three the TSVs.

According to the electronic device described above, each of the driving units comprises a transmitting unit, a selector, and a switch circuit. The transmitting unit receives the double pulse signal. Based on the double pulse signal, the transmitting unit generates the pulse signal. The selector receives the test result of the pulse signal. Based on the test result, the selector outputs a repair control signal. Based on the repair control signal from the selector, the switch circuit sends the pulse signal to the one of the redundant TSVs.

According to the electronic device described above, the selector comprises a multiplexer, including a first input terminal, a second input terminal, an output terminal, a control terminal, a state flip-flop, and a real-time repair logic circuit. The second input terminal receives the test result from the main controller. The control terminal receives a scan shift enable signal. The state flip-flop stores the test result. The state flip-flop includes an input terminal and an output terminal. The input terminal of the state flip-flop is electronically coupled to the output terminal of the multiplexer. The output terminal of the state flip-flop is electronically coupled to the first input terminal of the multiplexer, the main controller, and the real-time repair logic circuit. The real-time repair logic circuit receives a repair signal. Based on the repair signal and the test result stored in the state flip-flop, the real-time repair logic circuit correspondingly outputs the repair signal to the switch circuit.

According to the electronic device described above, based on the scan shift enable signal, the multiplexer correspondingly outputs the test result stored in the state flip-flop or the test result broadcasted by the main controller.

According to the electronic device described above, the main controller performs a pulse vanishing test. The main controller determines the test result by comparing the signal amplitude of the pulse signal that has passed through the TSVs with a predetermined threshold.

According to the electronic device described above, the receiving wrapper circuit comprises a plurality of receiving units. Each of the receiving units is electronically coupled to three of the TSVs.

According to the electronic device described above, each of the receiving units comprises a capture unit, a selector, and a switch circuit. The capture unit receives the pulse signal that has passed through the TSVs. The capture unit generates a test result based on the pulse signal that has passed through the TSVs. The selector receives the test result of the pulse signal. The selector outputs a repair control signal based on the test result. Based on the repair control signal from the selector, the switch circuit receives the pulse signal through the one of the redundant TSVs.

According to the electronic device described above, the selector comprises a multiplexer, including a first input terminal, a second input terminal, an output terminal, and a control terminal, wherein the second input terminal receives the test result from the sub-controller, and the control terminal receives a scan shift enable signal; a state flip-flop, storing the test result, and including an input terminal and an output terminal, wherein the input terminal of the state flip-flop is electronically coupled to the output terminal of the multiplexer; and a real-time repair logic circuit, electronically coupled to the state flip-flop, receiving a repair enable signal, and based on the repair enable signal and the test result stored in the state flip-flop, correspondingly outputting the repair signal to the switch circuit.

According to the electronic device described above, based on the scan shift enable signal, the multiplexer correspondingly outputs the test result generated by the capture unit or the test result sent by the sub-controller.

According to the electronic device described above, the main controller comprises a digitally controlled oscillator, based on the test result, outputting a first clock signal, a second clock signal, a third clock signal, a fourth clock signal, or a fifth clock signal; a control unit, electronically coupled to the digitally controlled oscillator, determining whether the test result shows that the test has succeed or failed, and correspondingly outputting a select signal and a double pulse enable signal; a multiplexer, based on the select signal, outputting the first clock signal, the second clock signal, the third clock signal, the fourth clock signal, or the fifth clock signal; and a double pulse generator, based on the double pulse enable signal, converting the first clock signal, the second clock signal, the third clock signal, the fourth clock signal, or the fifth clock signal to the double pulse signal.

According to the electronic device described above, the period of the first clock signal is greater than the period of the second clock signal; the period of the second clock signal is greater than the period of the third clock signal; the period of the third clock signal is greater than the period of the fourth clock signal; and the period of the fourth clock signal is greater than the period of the fifth clock signal.

The electronic device of the present invention further comprises a plurality of robust TSVs, electronically coupled to the base layer and the memory layers. The main controller broadcasts the test result to the sub-controller of each of the memory layers through the robust TSVs.

A method with built-in self-repair through-silicon vias (TSVs), in accordance with the embodiments of the present invention, is applicable for an electronic device with a plurality of TSVs and a plurality of dies. The method includes the following steps: performing a pulse vanishing test, including transmitting a pulse signal to the TSVs, and comparing the signal amplitude of the pulse signal that has passed through the TSVs with a predetermined threshold for determining a test result; broadcasting the test result; based on the test result, checking whether there are any faulty TSVs among the TSVs; in response to finding faulty TSVs, checking whether having enough a plurality of redundant TSVs among the TSVs; and in response to having enough redundant TSVs, performing a repair step, including selecting one of the backup TSVs to replace the faulty TSVs.

The method with built-in self-repair TSVs of the present invention further comprises shortening the pulse width of the pulse signal in the next test.

According to the method with built-in self-repair TSVs described above, steps of shortening the pulse width of the pulse signal in the next test comprise in response to not having any faulty TSVs, checking whether the pulse width of the pulse signal reaches the minimum test pulse width; in response to the pulse width of the pulse signal not reaching the minimum test pulse width, shortening the pulse width of the pulse signal by one test pulse width; and performing the pulse vanishing test again.

### BRIEF DESCRIPTION OF THE DRAWINGS

The present invention can be more fully understood by reading the subsequent detailed description and examples with references made to the accompanying drawings, wherein:

FIG. 1 is a three-dimensional schematic diagram of an electronic device 100, in accordance with the embodiments of the present invention.

FIG. 2 is a two-dimensional cross-sectional diagram of the electronic device 100, in accordance with the embodiments of the present invention.

FIG. 3 is a flowchart of a method with built-in self-repair through-silicon vias (TSVs), in accordance with the embodiments of the present invention.

FIG. 4 is a schematic diagram illustrating a driving wrapper circuit 108 and a receiving wrapper circuit 210 electronically coupled to TSV1-TSV10 in the electronic device 100 of FIG. 1, in accordance with the embodiments of the present invention.

FIG. 5 is a schematic diagram of a driving unit 400 in the driving wrapper circuit 108 of FIG. 4, in accordance with the embodiments of the present invention.

FIG. 6 is a schematic diagram of a receiving unit 420 in the receiving wrapper circuit 210 of FIG. 4, in accordance with the embodiments of the present invention.

FIG. 7 is a schematic diagram of a main controller 110 in the electronic device 100 of FIG. 1, in accordance with the embodiments of the present invention.

FIG. 8 is a schematic diagram of a digitally controlled oscillator 706 in the main controller 110 of FIG. 7, in accordance with the embodiments of the present invention.

FIG. 9 is a flowchart of a method with built-in self-repair TSVs, in accordance with the embodiments of the present invention.

FIG. 10 is a waveform timing diagram illustrating the electronic device 100 in FIG. 1 performing the method with built-in self-repair TSVs of FIG. 3, in accordance with the embodiments of the present invention.

FIG. 11A is a waveform timing diagram illustrating the electronic device 100 in FIG. 1 performing the method with built-in self-repair TSVs of FIG. 9, in accordance with the embodiments of the present invention.

FIG. 11B is another waveform timing diagram illustrating the electronic device 100 in FIG. 1 performing the method with built-in self-repair TSVs of FIG. 9, in accordance with the embodiments of the present invention.

FIG. 12 is a top-view layout diagram of a base layer 102 in the electronic device 100 of FIG. 1, in accordance with the embodiments of the present invention.

FIG. 13 is a schematic diagram of a repeater 1200 in the electronic device 100 of FIG. 1, in accordance with the embodiments of the present invention.

FIG. 14A is a waveform timing diagram of a double pulse signal DP in the electronic device 100 without repeaters 1200 and 1202, in accordance with the embodiments of the present invention.

FIG. 14B is a waveform timing diagram of a double pulse signal DP in the electronic device 100 with the repeaters 1200 and 1202, in accordance with the embodiments of the present invention.

### DETAILED DESCRIPTION OF THE INVENTION

The following description is made for the purpose of illustrating the general principles of the invention and should not be taken in a limiting sense. The scope of the invention is best determined by reference to the appended claims.

Exemplary embodiments of the present invention will now be described in detail, with examples illustrated in the accompanying drawings. Wherever possible, the same reference numerals are used throughout the drawings and description to refer to the same or like parts.

Certain terms are used throughout the specification and appended claims of the present invention to refer to specific components. Those skilled in the art should understand that electronic device manufacturers may refer to the same components by different names. This document does not intend to distinguish between components that have the same functionality but different names. In the following description and claims, terms such as “comprising”, “including”, and “containing” are open-ended and should be interpreted as “including, but not limited to”.

The terms “approximately”, “equal to”, “equivalent”, “substantially”, or “generally” are typically interpreted as being within 20% of a given value or range, or more specifically within 10%, 5%, 3%, 2%, 1%, or 0.5% of the given value or range.

The ordinal terms such as “first”, “second”, etc., used in the specification and claims are intended to modify elements and do not inherently imply any prior order or sequence of such elements, nor do they indicate any manufacturing sequence. These ordinal terms are used solely to distinguish one element with a given designation from another element with the same designation. The terminology used in the claims may differ from that in the specification; thus, a “first component” in the specification may correspond to a “second component” in the claims.

The terms “electrically coupled” or “coupled” as described in the present invention may refer to either a direct connection or an indirect connection. In the case of a direct connection, the terminals of two circuit elements are directly connected or interconnected by a conductive segment. In the case of an indirect connection, a switch, diode, capacitor, inductor, resistor, other suitable component, or a combination thereof may be present between the terminals of the two circuit elements, but the invention is not limited thereto.

In the present invention, measurements of thickness, length, and width may be obtained using an optical microscope, while thickness or width may also be measured from cross-sectional images in an electron microscope, though the methods are not limited to these. Additionally, any two compared numerical values or directions may have a certain margin of error. Furthermore, the terms “equal to”, “equivalent”, “identical”, “substantially”, or “generally” as used herein typically mean falling within a 10% range of a given value or range. Moreover, phrases such as “a given range from a first value to a second value” or “a given range falling within the range of a first value to a second value” indicate that the given range includes the first value, the second value, and all intermediate values.

It should be noted that the embodiments described below may be modified by replacing, recombining, or mixing features from different embodiments to create additional embodiments without departing from the spirit of the invention. Features from various embodiments may be freely combined as long as they do not conflict with the inventive spirit or contradict each other.

Unless otherwise defined, all terms (including technical and scientific terms) used herein have the same meaning as commonly understood by those skilled in the art to which the invention pertains. It is understood that terms defined in commonly used dictionaries should be interpreted in a manner consistent with their meaning in the context of the relevant technology and the background of the present invention, and should not be interpreted in an idealized or overly formal sense unless expressly defined as such in the embodiments of the invention.

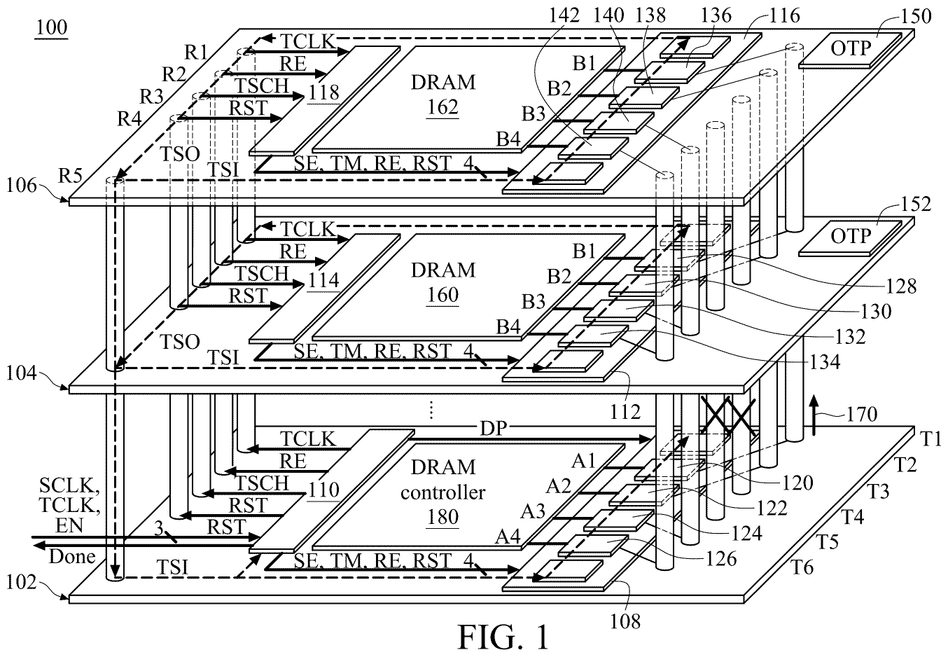

FIG. 1 is a three-dimensional schematic diagram of an electronic device 100, in accordance with the embodiments of the present invention. As shown in FIG. 1, the electronic device 100 includes a plurality of through-silicon vias (TSVs), a plurality of dies, and a plurality of robust TSVs. The plurality of TSVs may include, for example, TSVs T1, T2, T3, T4, T5, and T6. The plurality of dies may include, for example, a base layer 102, a memory layer 104, and a memory layer 106. The plurality of robust TSVs may include, for example, robust TSVs R1, R2, R3, R4, and R5. The plurality of dies are cascaded with each other through TSVs T1, T2, T3, T4, T5, T6 and robust TSVs R1, R2, R3, R4, R5.

In the embodiment of FIG. 1, the base layer 102 includes a main controller 110, a dynamic random access memory (DRAM) controller 180, and a driving wrapper circuit 108. The driving wrapper circuit 108 is electrically coupled to the main controller 110. The driving wrapper circuit 108 transmits a pulse signal 170 to the TSVs T1, T2, T3, T4, T5, T6, and based on a test result of the pulse signal 170, selects one of the redundant TSVs for transmitting the pulse signal 170 in the next test. The main controller 110 outputs a double pulse signal DP to the driving wrapper circuit 108, determines the test result, and broadcasts the test result through the robust TSVs R1, R2, R3, R4, R5. Furthermore, the main controller 110 outputs a scan shift enable signal SE, a test mode signal TM, a repair enable signal RE, and a reset signal RST to the driving wrapper circuit 108. The test mode signal TM causes the driving wrapper circuit 108 to enter a test mode. The repair signal RE causes the driving wrapper circuit 108 to perform a repair step. The reset signal RST is used to reset the driving wrapper circuit 108.

The driving wrapper circuit 108 includes a plurality of driving units. For example, the driving wrapper circuit 108 includes the driving units 120, 122, 124, and 126. In the embodiment of FIG. 1, based on the test result of the pulse signal 170, the driving wrapper circuit 108 determines that the TSVs T3 and T4 are faulty. Therefore, the driving unit 120 is electrically coupled to the TSV T1, the driving unit 122 is electrically coupled to the TSV T2, the driving unit 124 is electrically coupled to the TSV T5, and the driving unit 126 is electrically coupled to the TSV T6. The driving unit 120 is electrically coupled to a port A1 of the DRAM controller 180, the driving unit 122 is electrically coupled to a port A2 of the DRAM controller 180, the driving unit 124 is electrically coupled to a port A3 of the DRAM controller 180, and the driving unit 126 is electrically coupled to a port A4 of the DRAM controller 180.

The main controller 110 receives a clock signal SCLK, a clock signal TCLK, and a enable signal EN from the system side through a communication bus. The main controller 110 outputs a completion signal Done to the system side. Through the robust TSV R1, the main controller 110 transmits the clock signal TCLK to the memory layers 104 and 106. Through the robust TSV R2, the main controller 110 sends the repair signal RE to the memory layers 104 and 106. Through the robust TSV R3, the main controller 110 delivers a test scheduling signal TSCH to the memory layers 104 and 106. Through the robust TSV R4, the main controller 110 transmits the reset signal RST to the memory layers 104 and 106. Finally, through the robust TSV R5, the main controller 110 broadcasts the test result of the pulse signal 170 to the memory layers 104 and 106.

In some embodiments, the main controller 110 performs a pulse vanishing test. The main controller 110 compares the signal amplitude of the pulse signal that has passed through the TSVs T1, T2, T3, T4, T5, T6 with a predetermined threshold to determine the test result.

In the embodiment of FIG. 1, the memory layer 104 includes a sub-controller 114, a DRAM controller 160, a receiving wrapper circuit 112, and a one-time programmable memory (OTP) 150. The sub-controller 114 receives the test result from the main controller 110 and transmits the test result to the receiving wrapper circuit 112. The sub-controller 114 also outputs the scan shift enable signal SE, the test mode signal TM, the repair signal RE, and the reset signal RST to the receiving wrapper circuit 112. The receiving wrapper circuit 112 selects the one of the redundant TSVs based on the test result to receive the pulse signal 170.

The receiving wrapper circuit 112 includes a plurality of receiving units. For example, the receiving wrapper circuit 112 includes the receiving units 128, 130, 132, and 134. In the embodiment of FIG. 1, based on the test result of the pulse signal 170, the receiving wrapper circuit 112 determines that the TSVs T3 and T4 are faulty. Therefore, the receiving unit 128 is electrically coupled to the TSV T1, the receiving unit 130 is electrically coupled to the TSV T2, the receiving unit 132 is electrically coupled to the TSV T5, and the receiving unit 134 is electrically coupled to the TSV T6. The receiving unit 128 is electrically coupled to a port B1 of the DRAM controller 160, the receiving unit 130 is electrically coupled to a port B2 of the DRAM controller 160, the receiving unit 132 is electrically coupled to a port B3 of the DRAM controller 160, and the receiving unit 134 is electrically coupled to a port B4 of the DRAM controller 160.

The sub-controller 114 receives the clock signal TCLK from the main controller 110 through the robust TSV R1. The sub-controller 114 receives the repair signal RE from the main controller 110 through the robust TSV R2. The sub-controller 114 receives the test scheduling signal TSCH from the main controller 110 through the robust TSV R3. The sub-controller 114 receives the reset signal RST from the main controller 110 through the robust TSV R4. The receiving wrapper circuit 112 receives the test result (e.g., a test result input TSI) of the pulse signal 170 from the main controller 110 through the robust TSV R5. In some embodiments, the receiving wrapper circuit 112 outputs its stored test result (e.g., a test result output TSO) through the robust TSV R5. In some embodiments, since the memory layer 104 is an intermediate layer, the one-time programmable memory 150 is set to a logic low level, such as “0”.

Similarly, the memory layer 106 includes a sub-controller 118, a DRAM controller 162, a receiving wrapper circuit 116, and a one-time programmable memory (OTP) 152. The sub-controller 118 receives the test result from the main controller 110 and transmits the test result to the receiving wrapper circuit 116. The sub-controller 118 also outputs the scan shift enable signal SE, the test mode signal TM, the repair signal RE, and the reset signal RST to the receiving wrapper circuit 116. The receiving wrapper circuit 116 selects the one of the redundant TSVs based on the test result to receive the pulse signal 170.

The receiving wrapper circuit 116 includes a plurality of receiving units. For example, the receiving wrapper circuit 116 includes the receiving units 136, 138, 140, and 142. In the embodiment of FIG. 1, based on the test result of the pulse signal 170, the receiving wrapper circuit 116 determines that TSVs T3 and T4 are faulty. Therefore, the receiving unit 136 is electrically coupled to the TSV T1, the receiving unit 138 is electrically coupled to the TSV T2, the receiving unit 140 is electrically coupled to the TSV T5, and the receiving unit 142 is electrically coupled to the TSV T6. The receiving unit 136 is electrically coupled to a port B1 of the DRAM controller 162. The receiving unit 138 is electrically coupled to a port B2 of the DRAM controller 162. The receiving unit 140 is electrically coupled to a port B3 of the DRAM controller 162. The receiving unit 142 is electrically coupled to a port B4 of the DRAM controller 162.

The sub-controller 118 receives the clock signal TCLK from the main controller 110 through the robust TSV R1. The sub-controller 118 receives the repair signal RE from the main controller 110 through the robust TSV R2. The sub-controller 118 receives the test scheduling signal TSCH from the main controller 110 through the robust TSV R3. The sub-controller 118 receives the reset signal RST from the main controller 110 through the robust TSV R4. The receiving wrapper circuit 116 receives the test result (e.g., a test result input TSI) of the pulse signal 170 from the main controller 110 through the robust TSV R5. In some embodiments, the receiving wrapper circuit 116 outputs its stored test result (e.g., a test result output TSO) through the robust TSV R5. In some embodiments, since the memory layer 106 is the topmost layer, the one-time programmable memory 152 is set to a logic high level (e.g., “1”). In the embodiment of FIG. 1, during the next test, the pulse width of the pulse signal 170 is shortened.

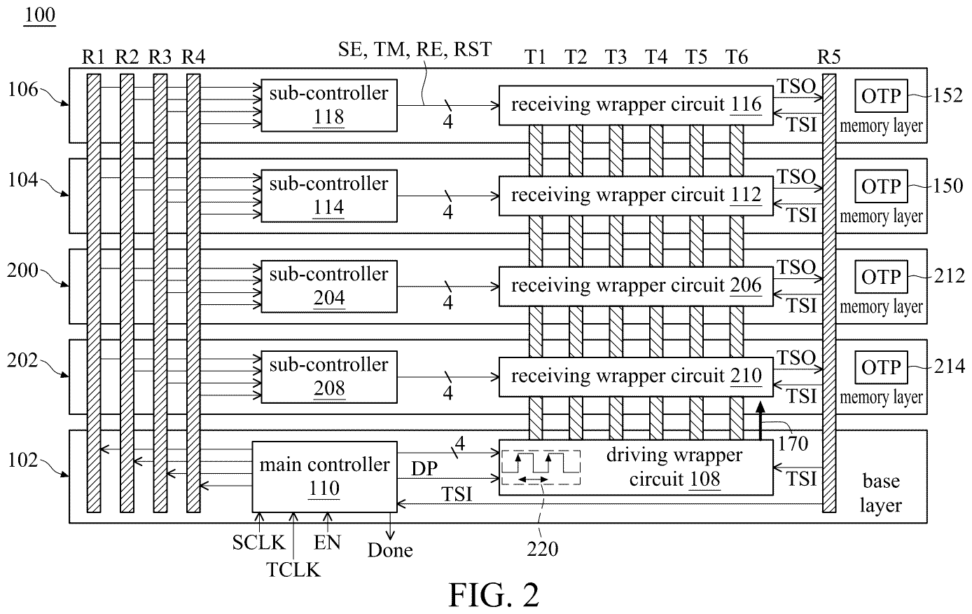

FIG. 2 is a two-dimensional cross-sectional diagram of the electronic device 100, in accordance with the embodiments of the present invention. Compared with FIG. 1, the electronic device 100 in FIG. 2 further comprises a memory layer 200 and a memory layer 202. The memory layer 200 includes a sub-controller 204, a receiving wrapper circuit 206, and a one-time programmable memory 212. The memory layer 202 includes a sub-controller 208, a receiving wrapper circuit 210, and a one-time programmable memory 214. The receiving wrapper circuit 206 and 210 each receive the test result (e.g., test result input TSI) of the pulse signal 170 from the main controller 110 through the robust TSV R5. In some embodiments, the receiving wrapper circuit 116 outputs its stored test result (e.g., test result output TSO) through the robust TSV R5. The sub-controller 204 further outputs the scan shift enable signal SE, the test mode signal TM, the repair signal RE, and the reset signal RST to the receiving wrapper circuit 206. Similarly, the sub-controller 208 further outputs the scan shift enable signal SE, test mode signal TM, repair signal RE, and reset signal RST to the receiving wrapper circuit 210.

In the embodiment of FIG. 2, the driving wrapper circuit 108 generates the pulse signal 170 based on a double pulse signal DP (as waveform 220 shows). The main controller 110 reduces the time interval between two rising edges of the double pulse signal DP such that the driving wrapper circuit 108 shortens the pulse width of the pulse signal 170. In some embodiments, since both the memory layers 200 and 202 are intermediate layers, the one-time programmable memories 212 and 214 are set to a logic low level (e.g., “0”).

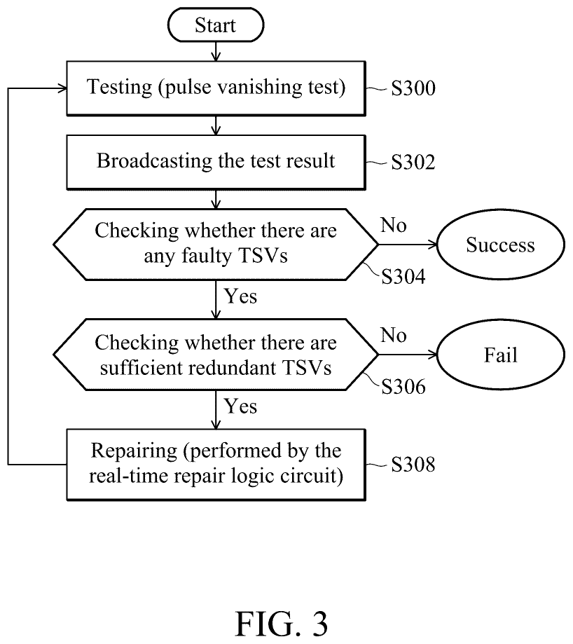

FIG. 3 is a flowchart of a method with built-in self-repair TSVs, in accordance with the embodiments of the present invention. As shown in FIG. 3, the method for built-in self-repair TSVs of the present invention is applicable to the electronic device 100 of FIG. 1 and includes the following steps. A pulse vanishing test is performed (step S300). Step S300 may be performed, for example, by the main controller 110 and the driving wrapper circuit 108 of FIG. 1. The pulse vanishing test includes transmitting a pulse signal to the TSVs and comparing the signal amplitude of the pulse signal that has passed through the TSVs with a predetermined threshold to determine the test result. The test result is broadcasted (step S302). Whether there are any faulty TSVs among the TSVs is checked based on the test result (step S304). If the result of step 304 is “yes”, whether having enough a plurality of redundant TSVs among the TSVs is checked (step S306). Steps S302-S306 may be performed, for example, by the main controller 110 of FIG. 1. If the result of step 306 is “yes”, a repair step is performed (step S308). The repair step includes selecting one of the redundant TSVs to replace the faulty TSV. Step S308 may be performed, for example, by the driving wrapper circuit 108 of FIG. 1 or independently by the receiving wrapper circuit 112 or 116 of FIG. 1.

In some embodiments, if the result of step S304 is “no”, the method with built-in self-repair TSVs of the present invention succeeds. If the result of step S306 is “no”, the method with built-in self-repair TSVs of the present invention fails.

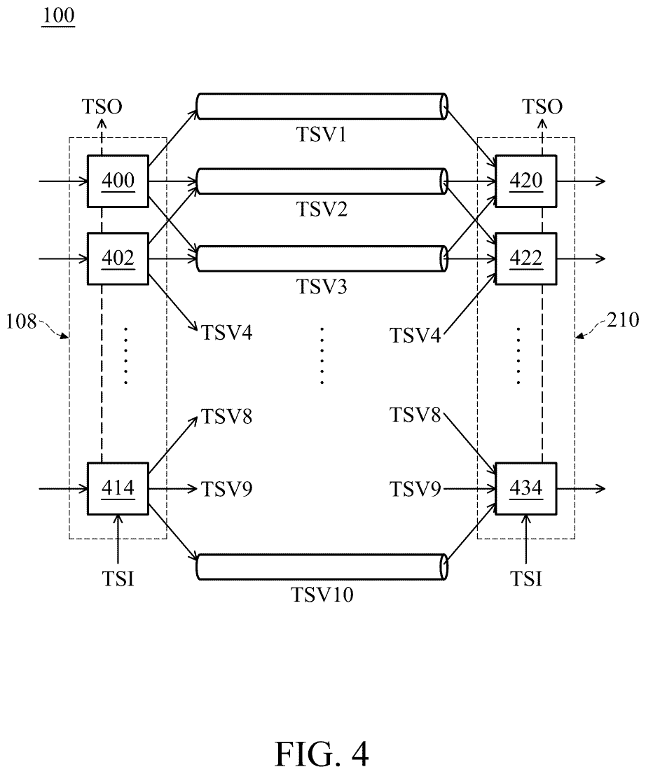

FIG. 4 is a schematic diagram illustrating the driving wrapper circuit 108 and the receiving wrapper circuit 210 electronically coupled to the TSV TSV1-TSV10 in the electronic device 100 of FIG. 1, in accordance with the embodiments of the present invention. As shown in FIG. 4, the driving wrapper circuit 108 includes driving units 400, 402, . . . , 414. The receiving wrapper circuit 210 includes receiving units 420, 422, . . . , 434. The driving unit 400 can select to be electronically coupled to the TSV TSV1, TSV2, or TSV3. The driving unit 402 can select to be electronically coupled to the TSV TSV2, TSV3, or TSV4. The driving unit 414 can select to be electronically coupled to the TSV TSV8, TSV9, or TSV10.

Similarly, the receiving unit 420 can be electrically coupled to the TSV TSV1, TSV2, or TSV3 selected by the driving unit 400. The receiving unit 422 can be electrically coupled to the TSV TSV2, TSV3, or TSV4 selected by the driving unit 402. The receiving unit 434 can be electrically coupled to the TSV TSV8, TSV9, or TSV10 selected by the driving unit 414.

In some embodiments, each driving unit is electrically coupled to three TSVs, but the present invention is not limited thereto. In some embodiments, the number of redundant TSVs may be, for example, 2, but the present invention is not limited thereto.

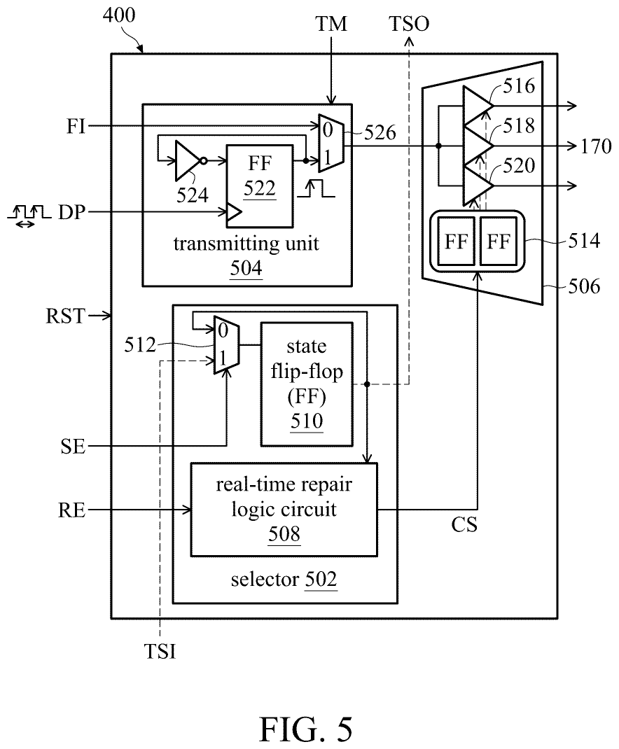

FIG. 5 is a schematic diagram of the driving unit 400 in the driving wrapper circuit 108 of FIG. 4, in accordance with the embodiments of the present invention. As shown in FIG. 5, the driving unit 400 includes a selector 502, a transmitting unit 504, and a switch circuit 506. The selector 502 receives the test result of the pulse signal 170 and, based on the test result, outputs a repair control signal CS to the switch circuit 506. The transmitting unit 504 receives a double pulse signal DP, and based on the double pulse signal DP, generates the pulse signal 170. The switch circuit 506 sends the pulse signal 170 to the one of the redundant TSVs according to the repair control signal CS from the selector 502.

In detail, the selector 502 includes a real-time repair logic circuit 508, a state flip-flop (FF) 510, and a multiplexer (MUX) 512. The real-time repair logic circuit 508 receives a repair signal RE and, based on the repair signal RE and the test result stored in the state flip-flop 510, outputs the repair control signal CS to the switch circuit 506. The state flip-flop 510 can also output the stored test result or the test result broadcasted by the main controller 110 through the test result output TSO. The multiplexer 512 includes a first input terminal, a second input terminal, an output terminal, and a control terminal. The first input terminal of the multiplexer 512 receives the test result stored in the state flip-flop 510. The second input terminal of the multiplexer 512 receives the test result from the main controller 110 through the test result input TSI. The control terminal of the multiplexer 512 receives the scan shift enable signal SE. The state flip-flop 510 includes an input terminal and an output terminal. The input terminal of the state flip-flop 510 is electrically coupled to the output terminal of the multiplexer 512. The output terminal of the state flip-flop 510 is electrically coupled to the first input terminal of the multiplexer 512, the main controller 110, and the real-time repair logic circuit 508.

In some embodiments, based on the scan shift enable signal SE, the multiplexer 512 correspondingly outputs the test result stored in the state flip-flop 510 or the test result broadcasted by the main controller 110.

In detail, the transmitting unit 504 includes a flip-flop (FF) 522, an inverter 524, and a multiplexer 526. The flip-flop 522 includes a first input terminal, a second input terminal, and an output terminal. The multiplexer 526 includes a first input terminal, a second input terminal, and an output terminal. The inverter 524 includes an input terminal and an output terminal. The first input terminal of the flip-flop 522 is electrically coupled to the output terminal of the inverter 524. The second input terminal of the flip-flop 522 receives the double pulse signal DP. The output terminal of the flip-flop 522 is electrically coupled to the second input terminal of the multiplexer 526 and the input terminal of the inverter 524. When the transmitting unit 504 receives the test mode signal TM from the main controller 110, the driving unit 400 enters the test mode, and the transmitting unit 504 begins receiving the double pulse signal DP and based on the double pulse signal DP, generates the pulse signal 170. The first input terminal of the multiplexer 526 receives a functional input signal FI. When the transmitting unit 504 does not receive the test mode signal TM from the main controller 110, the driving unit 400 is initially in a functional mode, and the functional input signal FI is sends to the TSV TSV1, TSV2, or TSV3 through the multiplexer 526 and the switch circuit 506.

In detail, the switch circuit 506 includes a flip-flop 514, switches 516, 518, and 520. The flip-flop 514 receives the repair control signal CS from the real-time repair logic circuit 508 and, based on the repair control signal CS, correspondingly generates a switch control signal to turn on one of the switches 516, 518, or 520 while keeping the other two off, thereby selecting the redundant TSV.

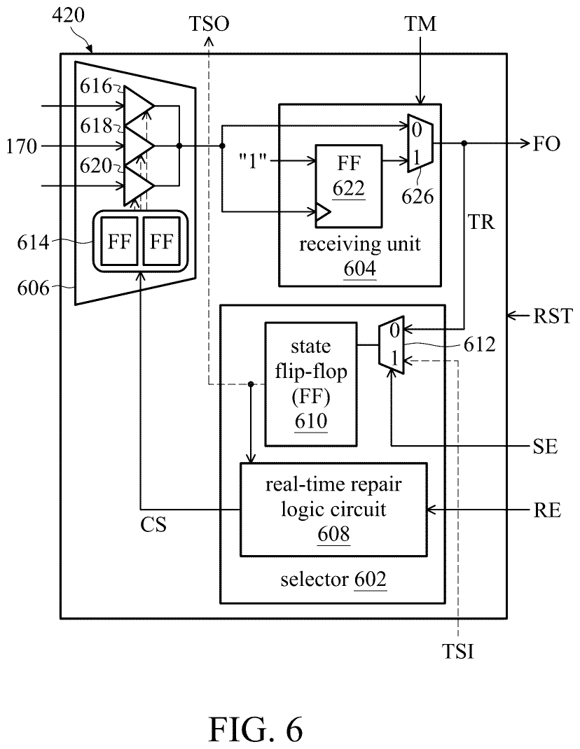

FIG. 6 is a schematic diagram of the receiving unit 420 in the receiving wrapper circuit 210 of FIG. 4, in accordance with the embodiments of the present invention. As shown in FIG. 6, the receiving unit 420 includes a selector 602, a switch circuit 606, and a capture unit 604. The capture unit 604 receives the pulse signal that has passed through the TSVs and based on the pulse signal, generates the test result TR. The selector 602 receives the test result TR of the pulse signal and, based on the test result TR, outputs a repair control signal CS. Based on the repair control signal CS from the selector 602, the switch circuit 606 receives the pulse signal 170 through the one of the redundant TSVs.

In detail, the selector 602 includes a real-time repair logic circuit 608, a state flip-flop (FF) 610, and a multiplexer 612. The real-time repair logic circuit 608 is electrically coupled to the state flip-flop 610. The real-time repair logic circuit 608 receives a repair signal RE and, based on the repair signal RE and the test result stored in the state flip-flop 610, outputs the repair control signal CS to the switch circuit 606. The multiplexer 612 includes a first input terminal, a second input terminal, an output terminal, and a control terminal. The state flip-flop 610 includes an input terminal and an output terminal. In some embodiments, the state flip-flop 610 can also output the stored test result or the test result sent by a sub-controller through the test result output TSO. The first input terminal of the multiplexer 612 receives the test result TR from the capture unit 604. The second input terminal of the multiplexer 612 receives the test result from the sub-controller through the test result input TSI. The control terminal of the multiplexer 612 receives the scan shift enable signal SE from the sub-controller. The output terminal of the multiplexer 612 is electrically coupled to the input terminal of the state flip-flop 610. The output terminal of the state flip-flop 610 is electrically coupled to the real-time repair logic circuit 608 and the main controller 110.

In some embodiments, based on the scan shift enable signal SE, the multiplexer 612 correspondingly outputs the test result TR generated by the capture unit 604 or the test result sent by the sub-controller.

In detail, the capture unit 604 includes a flip-flop (FF) 622 and a multiplexer 626. The flip-flop 622 includes a first input terminal, a second input terminal, and an output terminal. The multiplexer 626 includes a first input terminal, a second input terminal, a control terminal, and an output terminal. The first input terminal of the flip-flop 622 is electrically coupled to a logic high level (e.g., “1”). The second input terminal of the flip-flop 622 receives the pulse signal 170 that has passed through the TSVs. The output terminal of the flip-flop 622 is electrically coupled to the second input terminal of the multiplexer 626. The first input terminal of the multiplexer 626 is electrically coupled to the second input terminal of the flip-flop 622. When the capture unit 604 receives a test mode signal TM from the sub-controller, the receiving unit 420 enters a test mode, and the multiplexer 626 generates the test result TR based on the pulse signal that has passed through the TSVs. When the capture unit 604 does not receive the test mode signal TM from the sub-controller, the receiving unit 420 enters a functional mode, converts the functional input signal FI that has passed through the TSVs into a functional output signal FO, and outputs the functional output signal FO. In some embodiments, the functional output signal FO is identical to the functional input signal FI.

In detail, the switch circuit 606 includes a flip-flop 614, a switch 616, 618, and 620. The flip-flop 614 receives the repair control signal CS from the real-time repair logic circuit 608 and, based on the repair control signal CS, correspondingly generates a switch control signal to turn on one of the switches 616, 618, or 620 while keeping the other two off, thereby receiving the pulse signal 170 through the one of the redundant TSVs.

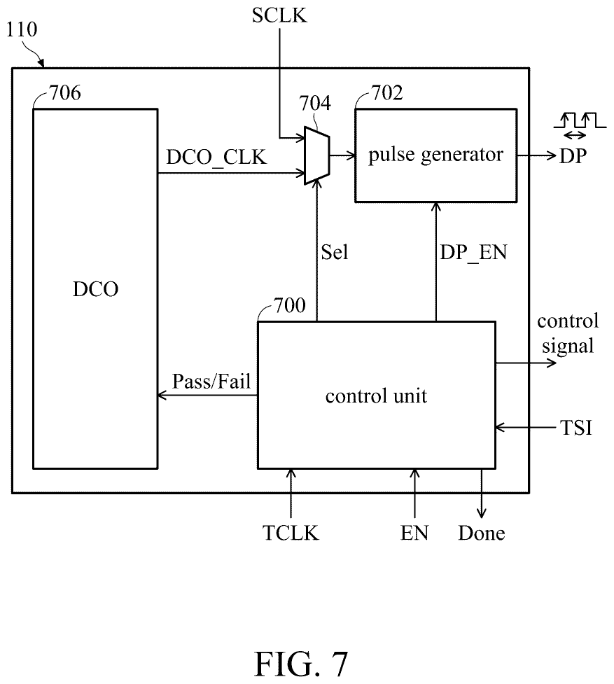

FIG. 7 is a schematic diagram of the main controller 110 in the electronic device 100 of FIG. 1, in accordance with the embodiments of the present invention. As shown in FIG. 7, the main controller 110 includes a control unit 700, a double pulse generator 702, a multiplexer 704, and a digitally controlled oscillator (DCO) 706. Based on the test result (e.g., the test result Pass or test result Fail), the digitally controlled oscillator 706 outputs a clock signal DCO_CLK. The clock signal DCO_CLK may be, for example, a first clock signal, a second clock signal, a third clock signal, a fourth clock signal, or a fifth clock signal. In some embodiments, the period of the first clock signal is longer than that of the second clock signal, the period of the second clock signal is longer than that of the third clock signal, the period of the third clock signal is longer than that of the fourth clock signal, and the period of the fourth clock signal is longer than that of the fifth clock signal. In some embodiments, the digitally controlled oscillator 706 outputs more than five clock signals with different periods. The present invention utilizes five of the clock signals with different periods output by the digitally controlled oscillator 706.

The control unit 700 is electrically coupled to the digitally controlled oscillator 706. The control unit 700 determines whether the test result received through the test result input TSI shows that the test has succeeded or failed, and correspondingly outputs a select signal Sel to the multiplexer 704 and a double pulse enable signal DP_EN to the double pulse generator 702. The control unit 700 also outputs multiple control signals (Control signals) to the driving wrapper circuit 108. In some embodiments, the control signals (Control signals) may include the scan shift enable signal SE, the test mode signal TM, the repair signal RE, and the reset signal RST. In some embodiments, the control unit 700 further receives the clock signal TCLK and the enable signal EN from the system side. In some embodiments, the clock signal TCLK may be, for example, a low-speed system clock signal.

Based on the select signal Sel, the multiplexer 704 outputs the first clock signal, second clock signal, third clock signal, fourth clock signal, or fifth clock signal. The multiplexer 704 includes a first input terminal, a second input terminal, an output terminal, and a control terminal. The first input terminal of the multiplexer 704 receives the clock signal SCLK from the system side. In some embodiments, the clock signal SCLK is a high-speed system clock signal. The second input terminal of the multiplexer 704 receives the first clock signal, second clock signal, third clock signal, fourth clock signal, or fifth clock signal from the digitally controlled oscillator 706. The output terminal of the multiplexer 704 is electrically coupled to the double pulse generator 702. The control terminal of the multiplexer 704 receives the select signal Sel from the control unit 700.

Based on the double pulse enable signal DP_EN, the double pulse generator 702 converts the first clock signal, second clock signal, third clock signal, fourth clock signal, or fifth clock signal to a double pulse signal DP.

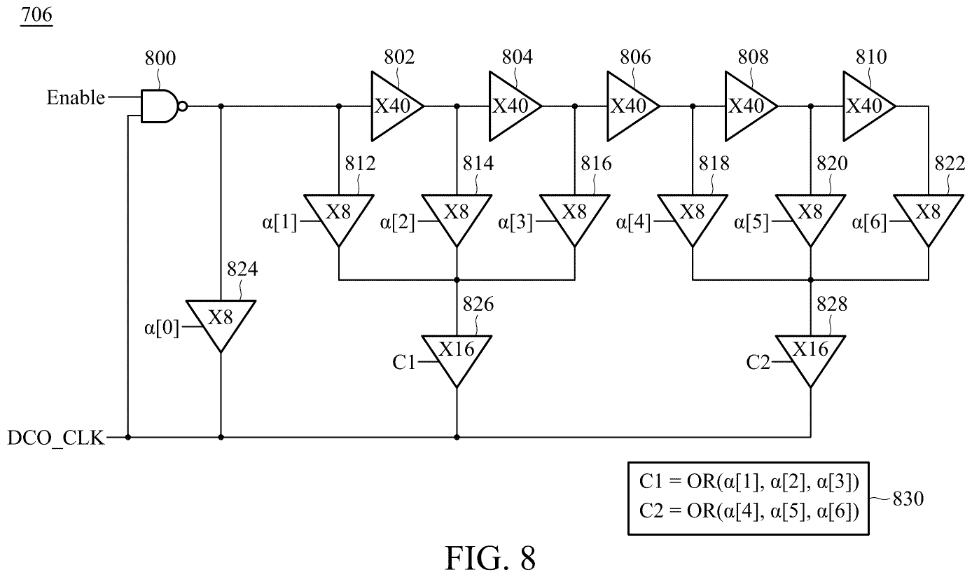

FIG. 8 is a schematic diagram of the digitally controlled oscillator 706 in the main controller 110 of FIG. 7, in accordance with the embodiments of the present invention. As shown in FIG. 8, the digitally controlled oscillator 706 includes a NAND gate 800, buffer gate groups 802, 804, 806, 808, 810, 812, 814, 816, 818, 820, 822, 824, 826, and 828. The NAND gate 800 includes a first input terminal, a second input terminal, and an output terminal. The first input terminal of the NAND gate 800 receives the enable signal EN. The second input terminal of the NAND gate 800 receives the clock signal DCO_CLK. Each of the buffer gate groups 802, 804, 806, 808, and 810 includes 40 buffer gates. The input terminal of the buffer gate group 802 is electrically coupled to the output terminal of the NAND gate 800. The output terminal of the buffer gate group 802 is electrically coupled to the input terminal of the buffer gate group 804. The output terminal of the buffer gate group 804 is electrically coupled to the input terminal of the buffer gate group 806. The output terminal of the buffer gate group 806 is electrically coupled to the input terminal of the buffer gate group 808. The output terminal of the buffer gate group 808 is electrically coupled to the input terminal of the buffer gate group 810.

Each of the buffer gate groups 812, 814, 816, 818, 820, 822, and 824 includes 8 buffer gates. Each of the buffer gate groups 826 and 828 includes 16 buffer gates. The input terminal of the buffer gate group 812 is electrically coupled to the output terminal of the NAND gate 800. The output terminal of the buffer gate group 812 is electrically coupled to the input terminal of the buffer gate group 826. The control terminal of the buffer gate group 812 receives a logic signal α[1]. The input terminal of the buffer gate group 814 is electrically coupled to the output terminal of the buffer gate group 802. The output terminal of the buffer gate group 814 is electrically coupled to the input terminal of the buffer gate group 826. The control terminal of the buffer gate group 814 receives a logic signal α[2]. The input terminal of the buffer gate group 816 is electrically coupled to the output terminal of the buffer gate group 804. The output terminal of the buffer gate group 816 is electrically coupled to the input terminal of the buffer gate group 826. The control terminal of the buffer gate group 816 receives a logic signal α[3].

The input terminal of the buffer gate group 818 is electrically coupled to the output terminal of the buffer gate group 806. The output terminal of the buffer gate group 818 is electrically coupled to the input terminal of the buffer gate group 828. The control terminal of the buffer gate group 818 receives a logic signal α[4]. The input terminal of the buffer gate group 820 is electrically coupled to the output terminal of the buffer gate group 808. The output terminal of the buffer gate group 820 is electrically coupled to the input terminal of the buffer gate group 828. The control terminal of the buffer gate group 820 receives a logic signal α[5]. The input terminal of the buffer gate group 822 is electrically coupled to the output terminal of the buffer gate group 810. The output terminal of the buffer gate group 822 is electrically coupled to the input terminal of the buffer gate group 828. The control terminal of the buffer gate group 822 receives a logic signal α[6]. The input terminal of the buffer gate group 824 is electrically coupled to the output terminal of the NAND gate 800. The output terminal of the buffer gate group 820 is electrically coupled to the clock signal DCO_CLK. The control terminal of the buffer gate group 824 receives a logic signal α[0]. The output terminals of both the buffer gate groups 826 and 828 are electrically coupled to the clock signal DCO_CLK. The control terminal of the buffer gate group 826 receives a logic signal C1, and the control terminal of the buffer gate group 828 receives a logic signal C2. Referring to block 830, C1=OR(α[1], α[2], α[3]), C2=OR(α[4], α[5], α[6]).

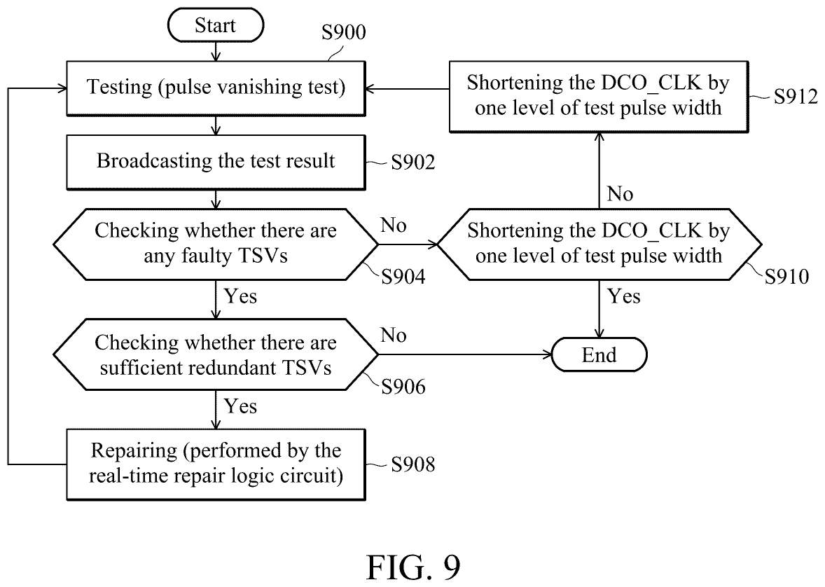

FIG. 9 is a flowchart of a method with built-in self-repair TSVs, in accordance with the embodiments of the present invention. As shown in FIG. 9, the method with built-in self-repair TSVs of the present invention is applicable to the electronic device 100 in FIG. 1, and includes the following steps. A pulse vanishing test is performed (Step S900). Step S900 may be performed, for example, by the main controller 110 and the driving wrapper circuit 108 in FIG. 1. The pulse vanishing test includes transmitting a pulse signal to the TSVs, and comparing the signal amplitude of the pulse signal that has passed through the TSVs with a predetermined threshold to determine the test result. The test result is broadcasted (Step S902). Based on the test result, whether there are any faulty TSVs among the TSVs is checked (Step S904). If the result of Step S904 is “yes”, whether having enough a plurality of redundant TSVs among the TSVs is checked (Step S906). Steps S902-S906 may be performed, for example, by the main controller 110 in FIG. 1. If the result of Step S906 is “yes”, a repair step is performed (Step S908). The repair step includes selecting one of the redundant TSVs to replace the faulty TSVs. Step S908 may be performed, for example, by the driving wrapper circuit 108 in FIG. 1, or independently by the receiving wrapper circuit 112 or 116 in FIG. 1.

In some embodiments, if the result of Step S904 is “no”, the method with built-in self-repair TSVs of the present invention further performs the following steps. Whether the pulse width of the pulse signal (or the period of the clock signal DCO_CLK) reaches the minimum test pulse width is checked (Step S910). If the result of Step S910 is “no”, the pulse width of the pulse signal (or the period of the clock signal DCO_CLK) is shorten by one level of test pulse width (Step S912), and then the pulse vanishing test is performed again (Step S900). If the result of Step S910 is “Yes”, the method with built-in self-repair TSVs of the present invention fails and ends. If the result of Step S906 is “no”, the method with built-in self-repair TSVs of the present invention fails and ends.

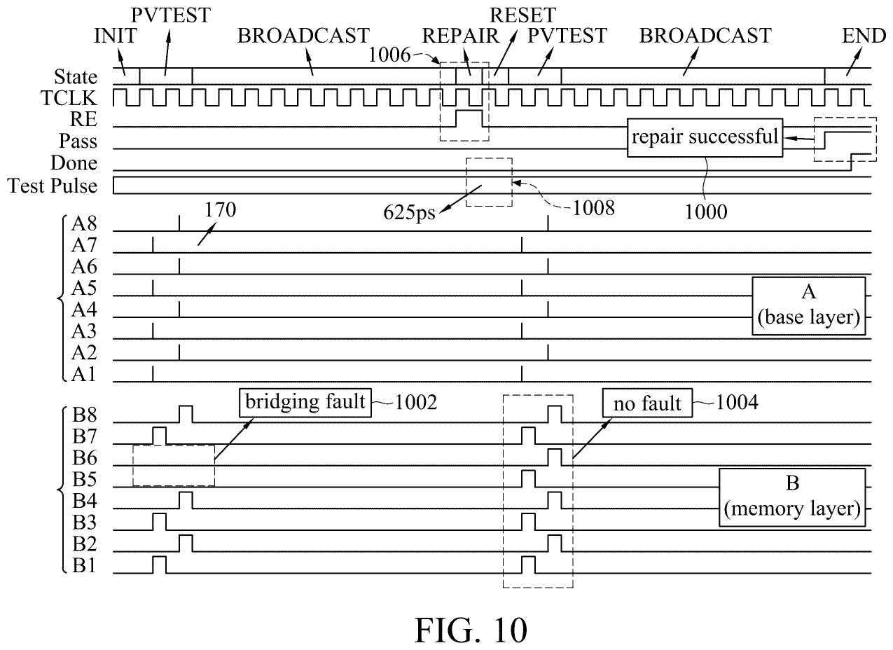

FIG. 10 is a waveform timing diagram illustrating the electronic device 100 of FIG. 1 performing the method with built-in self-repair TSVs of FIG. 3 by, in accordance with the embodiments of the present invention. Referring simultaneously to FIG. 10 and FIG. 1, FIG. 10 discloses the waveform diagrams of the state signal (state), clock signal TCLK, repair signal RE, test result Pass, completion signal Done, and pulse signal (Test Pulse) of the electronic device 100. In the embodiment of FIG. 10, the driving wrapper circuit 108 includes eight driving units, and each of the driving units is electrically coupled to ports A1-A8 of the DRAM controller 180, respectively. The receiving wrapper circuit 112 includes eight receiving units, and each of the receiving units is electrically coupled to ports B1-B8 of the DRAM controller 160, respectively. In other words, FIG. 10 illustrates the waveform of the pulse signal 170 when transmitted from the driving units of the ports A1-A8, and the waveform after being received by the receiving units of the ports B1-B8 through the TSVs.

The state signal (state) of the electronic device 100 may sequentially be, for example, an initial state INIT, a first pulse vanishing test PVTEST, a broadcast state BROADCAST, a repair state REPAIR, a reset state RESET, a second pulse vanishing test PVTEST, a broadcast state BROADCAST, and an end state END. Referring to block 1008, the driving units of the ports A1-A8 transmit pulse signals 170 with a pulse width of 625 picoseconds (ps) to the receiving units of the ports B1-B8, respectively. During the first pulse vanishing test PVTEST, if the receiving units of the ports B5 and B6 fail to receive the pulse signal 170 transmitted from the driving units of the ports A5 and A6, this constitutes detection of a “bridging fault” in block 1002.

In the broadcast state, the main controller 110 broadcasts the “bridging mal-function” to the sub-controllers 114 and 118. During the repair state REPAIR, block 1006 shows that the repair signal RE is pulled high, causing the receiving units of the ports B5 and B6 to perform repairs to select the redundant TSVs. In the second pulse vanishing test PVTEST, the receiving units of the ports B1-B8 successfully receive the pulse signals 170 transmitted from the driving units of the ports A1-A8, respectively. As a result, block 1004 displays “no fault”. In the subsequent broadcast state BROADCAST, the main controller 110 broadcasts “no fault” to the sub-controllers 114 and 118. As a result, block 1000 displays “repair successful”. After block 1000 shows “repair successful”, a logic level of the test result Pass is pulled high, and the completion signal Done is also pulled high.

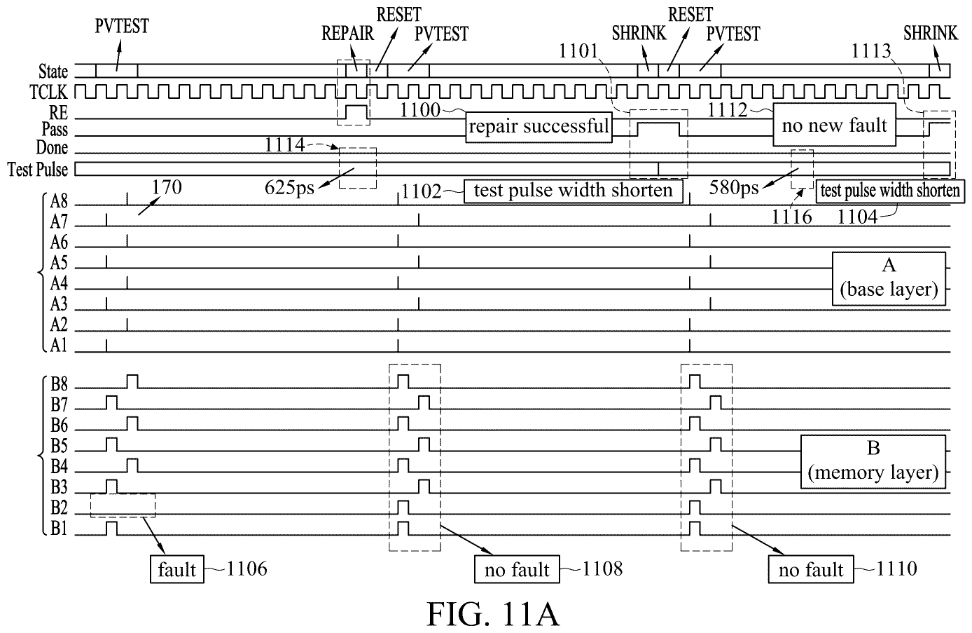

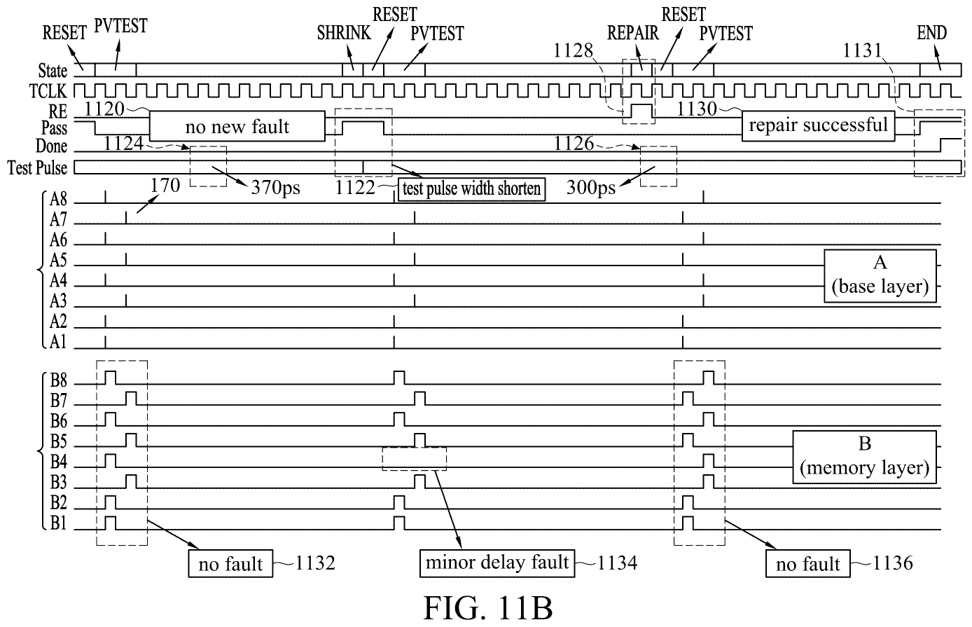

FIG. 11A is a waveform timing diagram illustrating the electronic device 100 of FIG. 1 performing the method with built-in self-repair TSVs of FIG. 9, in accordance with the embodiments of the present invention. Referring simultaneously to FIG. 11A and FIG. 1, FIG. 11A discloses the waveform diagrams of the state signal (state), clock signal TCLK, repair signal RE, test result Pass, completion signal Done, and pulse signal (Test Pulse) of the electronic device 100. In the embodiment of FIG. 11A, the driving wrapper circuit 108 includes eight driving units, and each of the driving units is electrically coupled to the ports A1-A8 of the DRAM controller 180, respectively. The receiving wrapper circuit 112 includes eight receiving units, and each of the receiving units is electrically coupled to the ports B1-B8 of the DRAM controller 160, respectively. In other words, FIG. 10 illustrates the waveform of the pulse signal 170 when transmitted from the driving units of the ports A1-A8, and the waveform after being received by the receiving units of ports the B1-B8 through the TSVs.

The state signal (state) of the electronic device 100 may sequentially be, for example, the initial state INIT, the first pulse vanishing test PVTEST, the broadcast state BROADCAST, the repair state REPAIR, the reset state RESET, the second pulse vanishing test PVTEST, the broadcast state BROADCAST, a pulse width shorten state SHRINK, a reset state RESET, a third pulse vanishing test PVTEST, and a pulse width shorten state SHRINK. Referring to block 1114, the driving units of the ports A1-A8 transmit the pulse signals 170 with a pulse width of 625 picoseconds (ps) to the receiving units of the ports B1-B8, respectively. During the first pulse vanishing test PVTEST, the receive unit of the port B2 fails to receive the pulse signal 170 transmitted from the driving unit of the port A2, thus detecting a “fault” in block 1106.

In the broadcast state, the main controller 110 broadcasts the “fault” to the sub-controllers 114 and 118. During the repair state REPAIR, the repair signal RE is pulled high, causing the receive unit of the port B2 to perform repairs to select the redundant TSVs. In the second pulse vanishing test PVTEST, the receiving units of the ports B1-B8 successfully receive the pulse signals 170 transmitted from the driving units of the ports A1-A8, respectively. As a result, block 1108 displays “no fault”. In the subsequent broadcast state BROADCAST, the main controller 110 broadcasts “no fault” to the sub-controllers 114 and 118. As a result, block 1100 displays “repair successful”. After block 1100 shows “repair successful”, the logic level of the test result Pass is pulled high as shown in block 1101, and the system enters the pulse width shorten state SHRINK. In the pulse width shorten state SHRINK, the main controller 110 performs a test pulse width shorten 1102, shortening the pulse width of the pulse signal from 625 ps in block 1114 to 580 ps in block 1116.

In the third pulse vanishing test PVTEST, the receiving units of the ports B1-B8 successfully receive the pulse signals 170 transmitted from the driving units of the ports A1-A8, respectively. As a result, block 1110 displays “no fault”. In the subsequent broadcast state BROADCAST, the main controller 110 broadcasts “no new fault” to the sub-controllers 114 and 118, as shown in block 1112. Then, in block 1113, the completion signal Done is pulled high, and the system enters the pulse width shorten state SHRINK. The subsequent waveform diagram will continue in FIG. 11B. In the final pulse width shorten state SHRINK of FIG. 11A, the main controller 110 performs a test pulse width shorten 1104, shortening the pulse width of the pulse signal from 580 ps in block 1116 to 370 ps in block 1124 of FIG. 11B.

FIG. 11B is a waveform timing diagram illustrating the electronic device 100 of FIG. 1 performing the method with built-in self-repair TSVs of FIG. 9, in accordance with the embodiments of the present invention. The state signal (state) of the electronic device 100 may sequentially be, for example, the reset state RESET, the first pulse vanishing test PVTEST, the broadcast state BROADCAST, the pulse width shorten state SHRINK, the reset state RESET, the second pulse vanishing test PVTEST, the broadcast state BROADCAST, the repair state REPAIR, the third pulse vanishing test PVTEST, and the end state END. During the first pulse vanishing test PVTEST, the receiving units of the ports B1-B8 successfully receive the pulse signals 170 transmitted from the driving units of the ports A1-A8, respectively. As a result, block 1132 displays “no fault”.

In the subsequent broadcast state BROADCAST, the main controller 110 broadcasts “no new fault” to the sub-controllers 114 and 118, and the logic level of the test result Pass is pulled high. The system then enters the pulse width shorten state SHRINK. In this state, the main controller 110 performs a time test pulse width shorten 1122, shortening the pulse width of the pulse signal from 370 ps in block 1124 to 300 ps in block 1126. During the second pulse vanishing test PVTEST, the receive unit of the port B4 fails to receive the pulse signal 170 transmitted from the driving unit of the port A4, thus detecting a “minor delay fault” in block 1134.

In the broadcast state, the main controller 110 broadcasts the “minor delay fault” to the sub-controllers 114 and 118. During the repair state REPAIR, the repair signal RE is pulled high as shown in block 1128, causing the receive unit of the port B4 to perform repairs to select the redundant TSVs. In the third pulse vanishing test PVTEST, the receiving units of the ports B1-B8 successfully receive the pulse signals 170 transmitted from the driving units of the ports A1-A8, respectively. As a result, block 1136 displays “no fault”. In the subsequent broadcast state BROADCAST, the main controller 110 broadcasts “no fault” to the sub-controllers 114 and 118. As a result, block 1130 displays “repair successful”. After block 1130 shows “repair successful”, the system enters the end state END. As shown in block 1131, the logic level of the test result Pass is pulled high, and the completion signal Done is also pulled high.

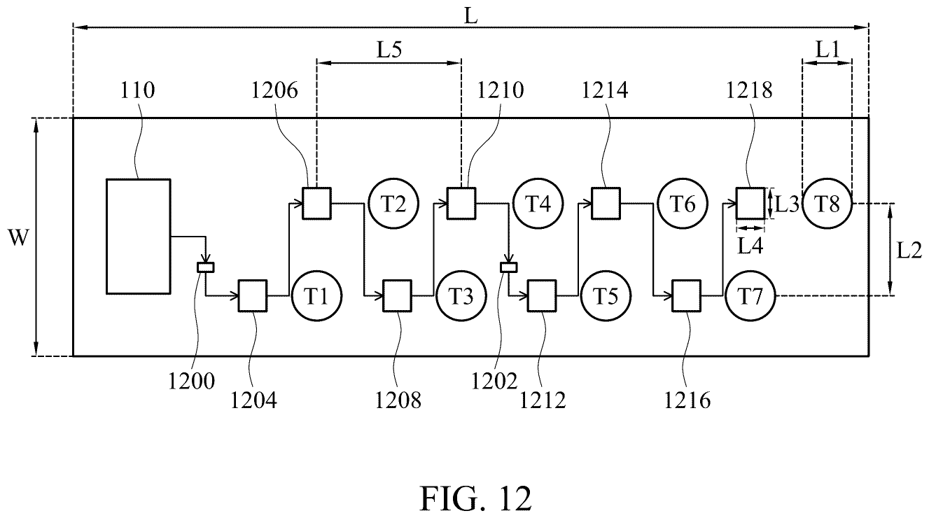

FIG. 12 is a top-view layout diagram of the base layer 102 in the electronic device 100 of FIG. 1, in accordance with the embodiments of the present invention. As shown in FIG. 12, the base layer 102 includes the main controller 110, a repeater 1200, a driving unit 1204, a TSV T1, a driving unit 1206, a TSV T2, a driving unit 1208, a TSV T3, a driving unit 1210, a TSV T4, a repeater 1202, a driving unit 1212, a TSV T5, a driving unit 1214, a TSV T6, a driving unit 1216, a TSV T7, a driving unit 1218, and a TSV T8, which are arranged in sequence. In some embodiments, the top-view layout diagram of FIG. 12 has a length L and a width W. The length L may, for example, be 532 micrometers (μm), and the width W may, for example, be 127 micrometers (μm).

The main controller 110 transmits the double pulse signal DP to the driving units 1204, 1206, 1208, 1210, 1212, 1214, 1216, and 1218. Then, based on the double pulse signal DP, the driving units 1204, 1206, 1208, 1210, 1212, 1214, 1216, and 1218 generate the pulse signal 170 and transmit the pulse signal 170 to the TSV T1-T8, respectively. In the embodiment of FIG. 12, the waveform of the double pulse signal DP measured at the driving unit 1204 may, for example, be indicated as DP[1]. The waveform of the double pulse signal DP measured at the driving unit 1206 may, for example, be indicated as DP[2]. The waveform of the double pulse signal DP measured at the driving unit 1208 may, for example, be indicated as DP[3]. The waveform of the double pulse signal DP measured at the driving unit 1210 may, for example, be indicated as DP[4]. The waveform of the double pulse signal DP measured at the driving unit 1212 may, for example, be indicated as DP[5]. The waveform of the double pulse signal DP measured at the driving unit 1214 may, for example, be indicated as DP[6]. The waveform of the double pulse signal DP measured at the driving unit 1216 may, for example, be indicated as DP[7]. The waveform of the double pulse signal DP measured at the driving unit 1218 may, for example, be indicated as DP[8].

In some embodiments, the diameter of each of the TSV T1-T8 may, for example, be L1. The diameter L1 may, for example, be 28 micrometers (μm). The distance between the center of TSV T7 and the center of TSV T8 may, for example, be L2. The distance L2 may, for example, be 55 micrometers (μm). Each of the driving unit 1204-1218 has a length L4 and a width L3. The length L4 may, for example, be 16 micrometers (μm), and the width L3 may, for example, be 16 micrometers (μm). The distance between the driving unit 1206 and driving unit 1210 is L5, which may, for example, be 96 micrometers (μm). The repeaters 1200 and 1202 are used to compensate for the attenuation of the double pulse signal DP along the transmission path, ensuring that the waveform of double pulse signal DP is restored to a square wave.

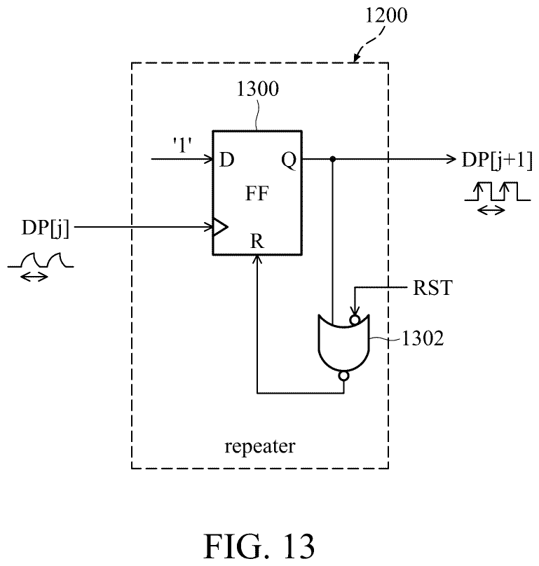

FIG. 13 is a schematic diagram of the repeater 1200 in the electronic device 100 of FIG. 1, in accordance with the embodiments of the present invention. As shown in FIG. 13, the repeater 1200 includes a flip-flop 1300 and a NOR gate 1302. In some embodiments, the flip-flop 1300 is a D-type flip-flop. The flip-flop 1300 includes a first input terminal, a second input terminal, a third input terminal, and an output terminal. The NOR gate 1302 includes a first input terminal, a second input terminal, and an output terminal. The first input terminal of the flip-flop 1300 is electrically coupled to a logic high level, such as “1”. The second input terminal of the flip-flop 1300 receives the double pulse signal DP[j]. The third input terminal of the flip-flop 1300 is electrically coupled to the output terminal of the NOR gate 1302. The output terminal of the flip-flop 1300 outputs the double pulse signal DP[j+1]. The first input terminal of the NOR gate 1302 receives the invert signal of the reset signal RST. The first input terminal of the NOR gate 1302 is electrically coupled to the output terminal of the flip-flop 1300.

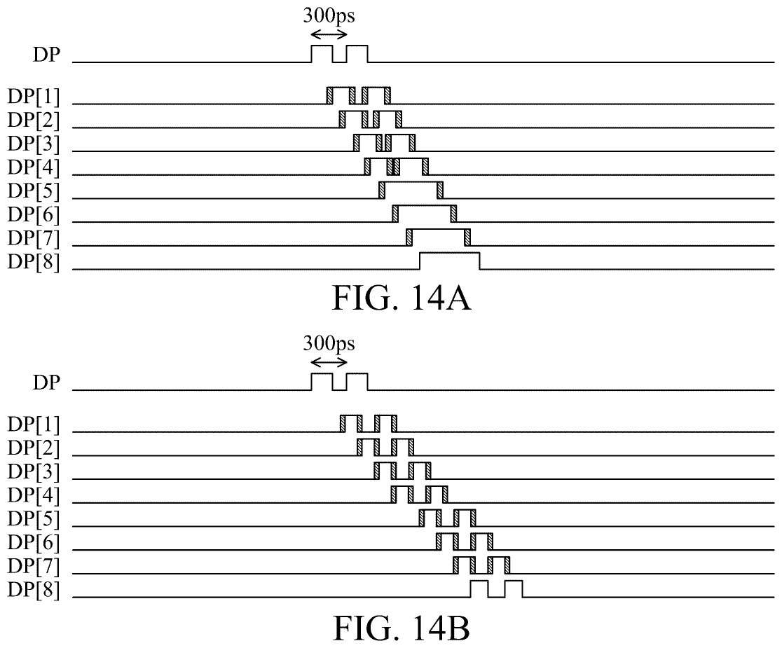

FIG. 14A is a waveform timing diagram of the double pulse signal DP in the electronic device 100 without the repeaters 1200 and 1202, in accordance with the embodiments of the present invention. As shown in FIG. 14A, the time interval between two rising edges of the double pulse signal DP is 300 picoseconds (ps). When the electronic device 100 does not include the repeaters 1200 and 1202, as the double pulse signal DP propagates along the transmission path, the waveforms DP[1]~DP[8] gradually distort, and even become a single pulse in waveforms DP[5]~DP[8].

FIG. 14B is a waveform timing diagram of the double pulse signal DP in the electronic device 100 with the repeaters 1200 and 1202, in accordance with the embodiments of the present invention. As shown in FIG. 14B, the time interval between the two rising edges of the double pulse signal DP remains at 300 picoseconds (ps). When the electronic device 100 includes the repeaters 1200 and 1202, as illustrated by waveforms DP[1]~DP[8], the double pulse signal DP consistently maintains the 300-picosecond interval between its two rising edges.

Although the embodiments of the present invention have been described as above, it should be understood that the foregoing is only illustrative and not restrictive. Numerous modifications to the exemplary embodiments described herein may be made without departing from the spirit and scope of the disclosure. Accordingly, the breadth and scope of the present invention should not be limited by the described embodiments. Rather, the scope of the invention should be defined by the appended claims and their equivalents. While the above disclosure has been illustrated and described with reference to one or more implementations, equivalent alterations and modifications will occur to those skilled in the art upon reading and understanding this specification and the accompanying drawings. Furthermore, although a particular feature of the invention may have been disclosed with respect to only one of several implementations, such feature may be combined with one or more other features as may be desired and advantageous for any given or particular application.

The terminology used in this specification is for the purpose of describing particular embodiments only and is not intended to limit the invention. Unless the context clearly indicates otherwise, singular forms such as “a”, “an”, and “the” include plural referents. Moreover, terms such as “comprising”, “including”, “having”, “provided with”, or variations thereof are intended to cover non-exclusive inclusion, meaning that elements or steps pre-ceded by these terms encompass not only the listed elements or steps but also other unlisted elements or steps. These terms are to be interpreted as synonymous with “including” unless otherwise specified. Unless otherwise defined, all terms (including technical and scientific terminology) used herein are to be understood in the ordinary sense by those skilled in the relevant art. It should be further understood that terms defined in commonly used dictionaries should be interpreted in a manner consistent with their meaning in the context of the relevant technology. Unless explicitly defined herein, such terms should not be interpreted in an idealized or overly formal sense.

While the invention has been described by way of example and in terms of the preferred embodiments, it should be understood that the invention is not limited to the dis-closed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An electronic device, comprising:
a plurality of through-silicon vias (TSVs), including a plurality of redundant TSVs; and
a plurality of dies, electronically cascaded to each other through the TSVs, and including a base layer and a plurality of memory layers;
wherein the base layer comprises:
a driving wrapper circuit, transmitting a pulse signal to the TSVs, and based on a test result of the pulse signal, selecting one of the redundant TSVs for transmitting the pulse signal in a next test; and
a main controller, outputting a double pulse signal, determining the test result, and broadcasting the test result;
wherein each of the memory layers comprises:
a receiving wrapper circuit, selecting the one of the redundant TSVs for receiving the pulse signal based on the test result; and
a sub-controller, receiving the test result, and sending the test result to the receiving wrapper circuit;
wherein in the next test, a pulse width of the pulse signal is shortened.

2. The electronic device as claimed in claim 1, wherein:
based on the double pulse signal, the driving wrapper circuit generates the pulse signal;
the main controller shortens a time interval between two rising edges of the double pulse signal such that the driving wrapper circuit shortens the pulse width of the pulse signal.

3. The electronic device as claimed in claim 1, wherein the driving wrapper circuit comprises:
a plurality of driving units;
each of the driving units is electronically coupled to three of the TSVs.

4. The electronic device as claimed in claim 3, wherein each of the driving units comprises:
an transmitting unit, receiving the double pulse signal, and based on the double pulse signal, generating the pulse signal;
a selector, receiving the test result of the pulse signal, and based on the test result, outputting a repair control signal; and
a switch circuit, sending the pulse signal to the one of the redundant TSVs based on the repair control signal from the selector.

5. The electronic device as claimed in claim 4, wherein the selector comprises:
a multiplexer, including a first input terminal, a second input terminal, an output terminal, and a control terminal, wherein the second input terminal receives the test result from the main controller, and the control terminal receives a scan shift enable signal;
a state flip-flop, storing the test result, and including an input terminal and an output terminal, wherein the input terminal of the state flip-flop is electronically coupled to the output terminal of the multiplexer, and the input terminal of the state flip-flop is electronically coupled to the first input terminal of the multiplexer; and
a real-time repair logic circuit, receiving a repair signal, and based on the repair signal and the test result stored in the state flip-flop, correspondingly outputting the repair signal to the switch circuit.

6. The electronic device as claimed in claim 5, wherein based on the scan shift enable signal, the multiplexer correspondingly outputs the test result stored in the state flip-flop or the test result broadcasted by the main controller.

7. The electronic device as claimed in claim 1, wherein:
the main controller performs a pulse vanishing test; and
the main controller determines the test result by comparing a signal amplitude of the pulse signal that has passed through the TSVs with a predetermined threshold.

8. The electronic device as claimed in claim 1, wherein the receiving wrapper circuit comprises:
a plurality of receiving units; wherein
each of the receiving units is electronically coupled to three of the TSVs.

9. The electronic device as claimed in claim 8, wherein each of the receiving units comprises:
a capture unit, receiving the pulse signal that has passed through the TSVs, and based on the pulse signal that has passed through the TSVs, generating the test result;
a selector, receiving the test result of the pulse signal, and based on the test result, outputting a repair control signal; and
a switch circuit, receiving the pulse signal through the one of the redundant TSVs based on the repair control signal from the selector.

10. The electronic device as claimed in claim 9, wherein the selector comprises:
a multiplexer, including a first input terminal, a second input terminal, an output terminal, and a control terminal, wherein the second input terminal receives the test result from the sub-controller, and the control terminal receives a scan shift enable signal;
a state flip-flop, storing the test result, and including an input terminal and an output terminal, wherein the input terminal of the state flip-flop is electronically coupled to the output terminal of the multiplexer; and
a real-time repair logic circuit, electronically coupled to the state flip-flop, receiving a repair signal, and based on the repair signal and the test result stored in the state flip-flop, correspondingly outputting the repair signal to the switch circuit.

11. The electronic device as claimed in claim 10, wherein based on the scan shift enable signal, the multiplexer correspondingly outputs the test result generated by the capture unit or the test result sent by the sub-controller.

12. The electronic device as claimed in claim 2, wherein the main controller comprises:
a digitally controlled oscillator, based on the test result, outputting a first clock signal, a second clock signal, a third clock signal, a fourth clock signal, or a fifth clock signal;
a control unit, electronically coupled to the digitally controlled oscillator, determining whether the test result indicates success or failure, and correspondingly outputting a select signal and a double pulse enable signal;
a multiplexer, based on the select signal, outputting the first clock signal, the second clock signal, the third clock signal, the fourth clock signal, or the fifth clock signal; and
a double pulse generator, based on the double pulse enable signal, converting the first clock signal, the second clock signal, the third clock signal, the fourth clock signal, or the fifth clock signal to the double pulse signal.

13. The electronic device as claimed in claim 12, wherein:
a period of the first clock signal is greater than a period of the second clock signal;
the period of the second clock signal is greater than a period of the third clock signal;
the period of the third clock signal is greater than a period of the fourth clock signal; and
the period of the fourth clock signal is greater than a period of the fifth clock signal.

14. The electronic device as claimed in claim 1, further comprising:
a plurality of robust TSVs, electronically coupled to the base layer and the memory layers;
wherein the main controller broadcasts the test result to the sub-controller of each of the memory layers through the robust TSVs.

15. A method with built-in self-repair through-silicon vias (TSVs), applicable for an electronic device with a plurality of TSVs and a plurality of dies, the method comprising:
performing a pulse vanishing test, wherein the pulse vanishing test includes transmitting a pulse signal to the TSVs, and comparing a signal amplitude of the pulse signal that has passed through the TSVs with a predetermined threshold for determining a test result;
broadcasting the test result;
based on the test result, checking whether there are any faulty TSVs among the TSVs;
in response to having the faulty TSVs, checking whether having enough a plurality of redundant TSVs among the TSVs; and
in response to having enough redundant TSVs, performing a repair step, wherein the repair step includes selecting one of the redundant TSVs to replace the faulty TSVs.

16. The method with built-in self-repair TSVs as claimed in claim 15, further comprising shortening a pulse width of the pulse signal in a next test.

17. The method with built-in self-repair TSVs as claimed in claim 16, wherein the step of shortening the pulse width of the pulse signal in the next test comprises:
in response to not having the faulty TSVs, checking whether the pulse width of the pulse signal reaches a minimum test pulse width;
in response to the pulse width of the pulse signal not reaching the minimum test pulse width, shortening the pulse width of the pulse signal by one level of test pulse width; and
performing the pulse vanishing test again.
